(19) United States
(12) Patent Application Publication
(10) Pub. No.: US 2012/0227555 A1
(43) Pub. Date: Sep. 13, 2012

(54) INSERT MEMBER, APPARATUS FOR BLANKING PRINTED CIRCUIT FILM HAVING THE SAME AND METHOD OF BLANKING PRINTED CIRCUIT FILM USING THE APPARATUS

(75) Inventors: MINILL KIM, Cheonan-si (KR); SEUNGYU MYUNG, Asan-si (KR); TACKKEUN LEE, Seoul, (KR); NAKHWAN SEONG, Asan-si (KR); SHIN KIM, Asan-si (KR)

(73) Assignee: SAMSUNG ELECTRONICS CO., LTD., Suwon-si (KR)

(21) Appl. No.: 13/185,791

(22) Filed: Jul. 19, 2011

(30) Foreign Application Priority Data
Mar. 9, 2011 (KR) 10-2011-0020976

(51) Int. Cl. B26F 1/38; B26D 7/01; H05K 3/00

(52) U.S. Cl. 83/55; 83/694; 83/651

(57) ABSTRACT

An apparatus for blanking a printed circuit film includes a die unit and a punch unit movable with respect to the die unit. The die unit includes a plate, and an insert member which is on a top surface of the plate and supports a region of a base film which is punched. The insert member supports the base film including a plurality of printed circuit films, and as a punch is lowered, the punch punches the base film and is inserted in an opening of the insert member so as to blank the printed circuit film. The insert member further includes a plurality of assembled detachable frames which define the opening of the insert member.

This application claims priority to Korean Patent Application No. 10-2011-0020976, filed on Mar. 9, 2011, and all the benefits accruing therefrom under 35 U.S.C. §119, the entire contents of which are hereby incorporated by reference.

### BACKGROUND OF THE INVENTION

(1) Field of the Invention

The disclosure herein relates to an insert member, an apparatus including the insert member for blanking a printed circuit film, and a method of blanking a printed circuit film using the apparatus.

(2) Description of the Related Art

In liquid crystal displays, a voltage is applied to molecules of liquid crystal to change the molecular arrangement of the liquid crystal, and then optical characteristics such as birefringence, optical rotation, and light scattering of liquid crystal cells are accordingly changed so that information can be displayed by modulating light using the change of optical characteristics of the liquid crystal cells. Liquid crystal displays are used in almost all flat display products such as cellular phones, monitors, and televisions (“TVs”). Owing to recent rapid advance in technology, high-quality, light, slim liquid crystal display products are available.

In a liquid crystal display, a liquid crystal panel and a printed circuit board are electrically connected to each other through a flexible printed circuit film. If an integrated circuit chip is disposed on a flexible printed circuit film, the flexible printed circuit film may be used as a chip on film (“COF”) or a tape carrier package (“TCP”). Flexible printed circuit films having a predetermined size may be fabricated by punching a base film with a punch.

### BRIEF SUMMARY OF THE INVENTION

The disclosure provides an insert member that includes an opening and can be easily grinded at the inner surface of the opening.

The disclosure also provides an insert member that can be manufactured with low cost.

The disclosure also provides an insert member which reduces a tolerance of a gap between an opening of the insert member and a punch

The disclosure also provides an apparatus and method for blanking a high-quality printed circuit film.

Embodiments of the invention provides apparatuses for blanking a printed circuit film. The apparatuses blank a printed circuit film from a base film including a plurality of printed circuit films. The apparatus includes a die unit which supports the base film, and a vertically movable punch unit which is above the die unit and includes a punch which punches the base film while the base film is placed on the die unit, such that the printed circuit film is blanked from the base film. The die unit includes a plate, and an insert member which is on a top surface of the plate and supports a region of the base film which is punched. The insert member includes an opening which receives the punch. The insert member further includes a plurality of assembled detachable frames, and the opening of the insert member is defined by the assembled the frames. The insert member may have a tetragonal rim shape.

In some embodiments, the insert member may include four frames each having a rectangular parallelepiped shape. Neighboring frames may be disposed such that an end of one of the neighboring frames contacts a side of the other of the neighboring frames. One side of the opening may be defined by one side of one of the frames.

In other embodiments, the frames may include a first frame, a second frame which is spaced apart from the first frame and parallel with the first fame, a third frame perpendicular to the first frame, the third frame including a first end which contacts a side of the first frame and a second end which opposes the first end and contacts a side of the second frame, and a fourth frame which is spaced apart from the third frame and parallel with the third frame, the fourth frame including a first end which contacts the side of the first frame and a second end which opposes the first end and contacts with the side of the second frame.

In still other embodiments, the insert member may include two frames having the same shape. Each of the frames may include a first region, a second region which extends from a first end of the first region, in a direction perpendicular to the first region, and a third region which extends from a second end of the first region which opposes the first end, in a direction perpendicular to the first region, the third region facing the second region.

In even other embodiments, the insert member may include eight frames having the same shape. Each of the eight frames may include a first side, a second side parallel with the first side and longer than the first side, a third side perpendicular to the first side, the third side connecting a first end of the first side and a first end of the second side, and a fourth side connecting a second opposing the first end of the first side and a second end opposing the first end of the second side.

In yet other embodiments, each of the frames may include an insertion protrusion, and an insertion groove having a shape which corresponds to the insertion protrusion and receives the insertion protrusion of an adjacent frame.

In further embodiments, a portion of the frames includes a first stepped portion at an outer region of the frame, such that a top surface of the outer region is lower than a top surface of an inner region of the frame close to the opening. The die unit may further include an insert fixation part which is coupled to the plate. An end of the insert fixation part includes a second stepped portion in a shape corresponding to the outer region of the frame. A bottom surface of the second stepped portion of the insert fixation part contacts the top surface of the outer region of the frame.

In other embodiments of the invention, there are provided insert members for a printed circuit film blanking apparatus in which a portion of a base film including a plurality of printed circuit films is supported on the insert member and is punched by a punch to blank the printed circuit film. The insert member includes detachable frames assembled in a tetragonal rim shape, and an opening which receives the punch and is defined by the assembled frames.

In some embodiments, the insert member may include four frames each having a rectangular parallelepiped shape.

In other embodiments, the insert member may include two frames having the same “C”-shape (square bracket shape).

In still other embodiments, the insert member may include four frames having the same [symbol] -shape (bracket shape).

In still other embodiments of the invention, there are provided a method of blanking a printed circuit film, the method including providing an insert member including an opening, placing a portion of a base film including a plurality of printed circuit films on a top surface of the insert member, and blanking the printed circuit film by lowering a punch from an upper side of the insert member into the opening of the insert member, The insert member includes a plurality of detachable frames which are assembled and define the opening.

In some embodiments, prior to the providing the insert member, the method may further include performing a position setting operation to fix positions of a first plate which receives the insert member and a second plate on which the punch is disposed to blanking positions, such that the punch blanks the printed circuit film. The position setting operation may be performed in a state where the punch is detached and a jig is attached to a position from which the punch is detached.

In other embodiments, the jig may have the same shape as the punch.

In still other embodiments, a bottom surface of the jig may be wider than the opening.

In even other embodiments, the providing of the insert member may include detaching the jig from the position and attaching the punch to the position, and placing the first plate and the second plate at the blanking positions.

### BRIEF DESCRIPTION OF THE DRAWINGS

The accompanying drawings are included to provide a further understanding of the invention, and are incorporated in and constitute a part of this specification. The drawings illustrate exemplary embodiments of the invention concept and, together with the description, serve to explain principles of the invention concept. In the drawings:

FIG. 1 is an exploded perspective view illustrating an exemplary embodiment of an apparatus for blanking a printed circuit film according to the invention;

FIG. 2 is a cross-sectional view illustrating the printed circuit film blanking apparatus illustrated in FIG. 1;

FIGS. 3A through 3F are plan views illustrating exemplary embodiments of insert members according to the invention;

FIGS. 4 and 5 are views for explaining an exemplary embodiment of a position setting operation according to the invention;

FIGS. 6 through 9 are views for explaining an exemplary embodiment of an assembling operation according to the invention;

FIG. 10 is a perspective view illustrating an exemplary embodiment of a base film supported on a die unit according to the invention;

FIG. 11 is a cross-sectional view for explaining an exemplary embodiment of an operation of blanking a printed circuit film using a punch unit according to the invention;

FIG. 12 is a perspective view illustrating another exemplary embodiment of a jig according to the invention; and

FIG. 13 is a cross-sectional view for explaining an exemplary embodiment of a position setting operation using the jig of FIG. 12 according to the invention.

### DETAILED DESCRIPTION OF THE INVENTION

Exemplary embodiments of the invention will be described below in more detail with reference to the accompanying drawings. The invention may, however, be embodied in different forms and should not be construed as limited to the embodiments set forth herein. Various modifications, equivalents, and substitutes may be provided within the scope and spirit of the invention.

In the following descriptions of the drawings, like reference numerals refer to like elements. In addition, the dimensions of elements are exaggerated for clarity of illustration. It will be understood that although the terms first and second are used herein to describe various elements, these elements should not be limited by these terms. These terms are used only to discriminate one element from another element. For example, an element referred as a first element in one embodiment may be referred to as a second element in another embodiment, and an element referred to as a second element in one embodiment may be referred to as a first element so long as this naming does not obscure the scope of the invention. The terms of a singular form may include plural forms unless referred to the contrary.

The meaning of “include,” “comprise,” “including,” or “comprising,” specifies a property, a region, a fixed number, a step, a process, an element, and/or a component but does not exclude other properties, regions, fixed numbers, steps, processes, elements and/or components. It will also be understood that when an element such as a layer, a film, a region, and a plate is referred to as being ‘on’ another element, it can be directly on the other element, or one or more intervening elements may also be present. Further, it will be understood that when an element such as a layer, a film, a region, and a plate is referred to as being ‘under’ another element, it can be directly under, and one or more intervening elements may also be present. In addition, it will also be understood that when an element is referred to as being ‘between’ two elements, it can be the only element between the two elements, or one or more intervening elements may also be present.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

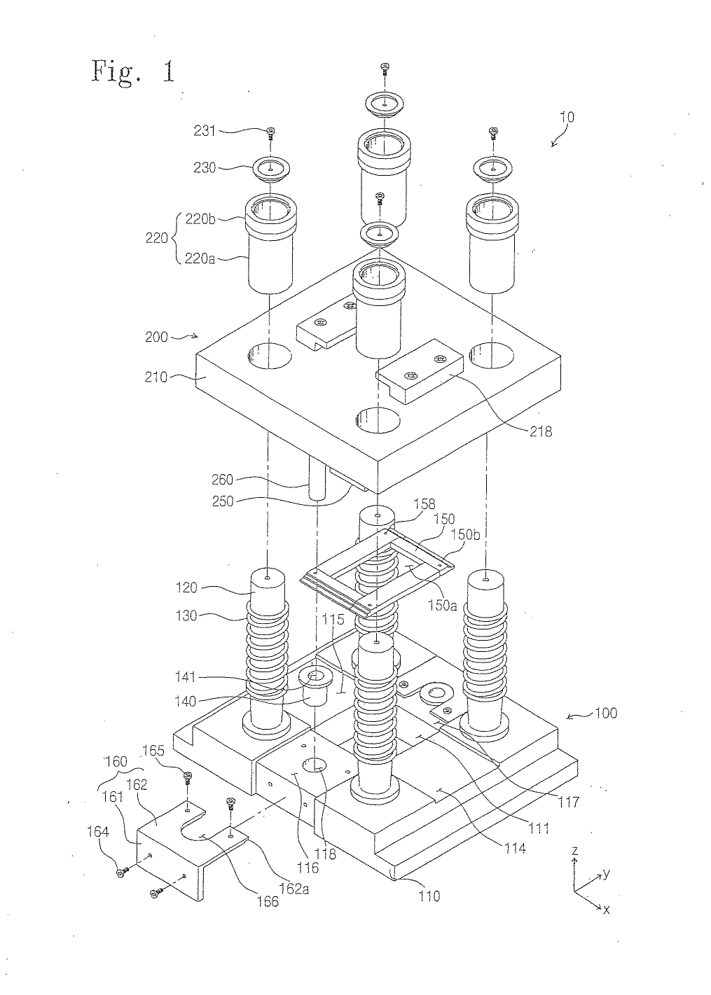

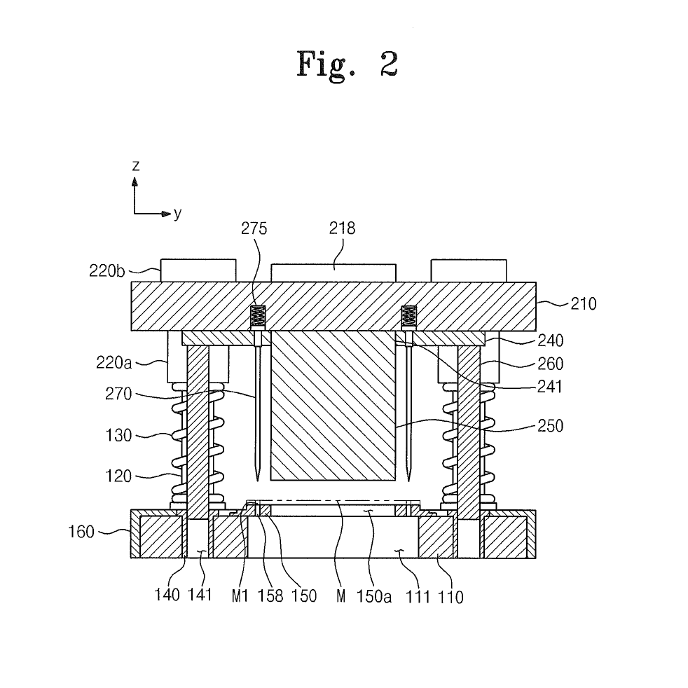

FIG. 1 is an exploded perspective view illustrating an exemplary embodiment of an apparatus 10 for blanking a printed circuit film according to the invention, and FIG. 2 is a cross-sectional view illustrating the printed circuit film blanking apparatus 10 in FIG. 1.

Referring to FIGS. 1 and 2, the printed circuit film blanking apparatus 10 is used to blank printed circuit films from a base film by punching the base film. The printed circuit film blanking apparatus 10 includes a die unit 100 and a punch unit 200. The die unit 100 supports a portion of a base film to be punched, and the punch unit 200 punches the base film supported on the die unit 100 to blank a printed circuit film. Hereinafter, elements of the printed circuit film blanking apparatus 10 will be described in more detail.

The die unit 100 includes a first plate 110, lift rods 120, elastic members 130, guide bushes 140, an insert member 150, and insert fixation parts 160.

The first plate 110 has a tetragonal shape. The first plate 110 includes a first opening 111 in a center portion. The first opening 111 extends from a top surface to a bottom surface of the first plate 110, completely through a thickness of the first plate 110, such as in the form of a penetration hole. The first opening 111 has an approximately tetragonal shape. Guide grooves 114 and 115 and insertion grooves 116 and 117 are extended in the top surface of the first plate 110. The guide grooves 114 and 115 are at both of opposing sides of the first opening 111 and extend from the first opening 111 to outer sides (e.g. edges) of the first plate 110. Hereinafter, a direction in which the guide grooves 114 and 115 and the first opening 111 are arranged will be referred to as a first direction X, and a direction perpendicular to the first direction X when viewed from the top side will be referred to as a second direction Y. A direction perpendicular to the first and second directions X and Y will be referred to as a third direction Z. The guide grooves 114 and 115 guide the base film M in the first direction X. The base film M is placed in the guide groove 114 at one side of the first opening 111 and is fed to the guide groove 115 at the opposing other side of the first opening 111 as a blanking process proceeds. The first direction X may also be referred to as a feeding direction of the base film M.

The insertion grooves 116 and 117 are at both of opposing sides of the first opening 111 in the second direction Y. When viewed from the top side of the first plate 110, the insertion grooves 116 and 117 and the guide grooves 114 and 115 are arranged around the first opening 111 in a cross shape. The insertion grooves 116 and 117 extend from the first opening 111 to outer sides of the first plate 110. The insert fixation parts 160 are fixedly inserted in the insertion grooves 116 and 117, respectively. Ends of the insert member 150 (described later) are placed in the insertion grooves 116 and 117, respectively. Bush holes 118 are extended into the bottom surfaces of the insertion grooves 116 and 117, respectively. The bush holes 118 are penetration holes which extend from the bottom surfaces of the insertion grooves 116 and 117 to the bottom surface of the first plate 110.

The lift rods 120 are on the topside of the first plate 110 and have a rod shape. The lengths of the lift rods 120 are parallel to the third direction Z, and the lower ends of the lift rods 120 are fixed to the top surface of the first plate 110. In an embodiment, the lift rods 120 are four in number and are in regions between the insertion grooves 116 and 117 and the guide grooves 114 and 115, respectively. When the punch unit 200 is vertically moved in the third direction Z to punch the base film M, the lift rods 120 guide the punch unit 200 along a preset path

The elastic members 130 are around the lift rods 120. When the punch unit 200 is moved down in the third direction Z toward the die unit 100 to punch the base film M, the elastic members 130 are compressed, and when the punch unit 200 is moved to its original position in the third direction Z away from the die unit 100, the elastic members 130 are decompressed. In an embodiment, the elastic members 130 may be springs.

The guide bushes 140 are inserted in the bush holes 118, respectively. The outer surfaces of the guide bushes 140 have the same radius as the inner surface of the bush holes 118 in the first plate 110. The guide bushes 140 include guide holes 141 are extended completely though a length of the guide bushes 140 in center regions of the guide bushes 140. The guide holes 141 are penetration holes which extend from the top surfaces to the bottom surfaces of the guide bushes 140. The guide holes 141 have a radius corresponding to dimensions of guide rods 260 (described later). The guide rods 260 are inserted in the guide holes 141.

The insert member 150 has a thin tetragonal rim shape. The insert member 150 is placed on the top surface of the first plate 110. In detail, one end of the insert member 150 is placed on the bottom surface of the (first) insertion groove 116, and the opposing other end of the insert member 150 is placed on the bottom surface of the (second) insertion groove 117. The top surface of the insert member 150 is higher than the bottom surfaces of the insertion grooves 116 and 117. A punch region of the base film M is on the top surface of the insert member 150.

The insert member 150 includes a second opening 150a. The second opening 150a is a penetration hole which extends from the top surface to the bottom surface of the insert member 150. The second opening 150a is above the first opening 111 and is connected to the first opening 111. When viewed from the topside of the second opening 150a, the second opening 150a has a rectangular shape and a size corresponding to a printed circuit film (not shown). A punch 250 is inserted in the second opening 150a after the punch 250 punches the base film M.

The insert member 150 further includes pin holes 158. The pin holes 158 are four in number and are spaced apart from each other. The pin holes 158 are in regions close to corners of the second opening 150a. The pin holes 158 are penetration holes which extend from the top surface to the bottom surface of the insert member 150 and are connected to the first opening 111. The pin holes 158 are connected to fixation holes M1 in the base film M. Fixation pins 270 are inserted in the fixation holes M1 and the pin holes 158 to fix the base film M when a printed circuit film is blanked using the punch 250. The insert member 150 is stepped in a manner such that the top surfaces of outer regions 150b spaced apart from the second opening 150a are lower than the top surface of an inner region close to the second opening 150a. In an embodiment, the insert member 150 is stepped in a manner such that the outer regions 150b are parallel to the first direction X.

In an embodiment, the insert member 150 may be formed by assembling a plurality of detachable frames in a tetragonal shape to define the second opening 150a of the insert member 150.

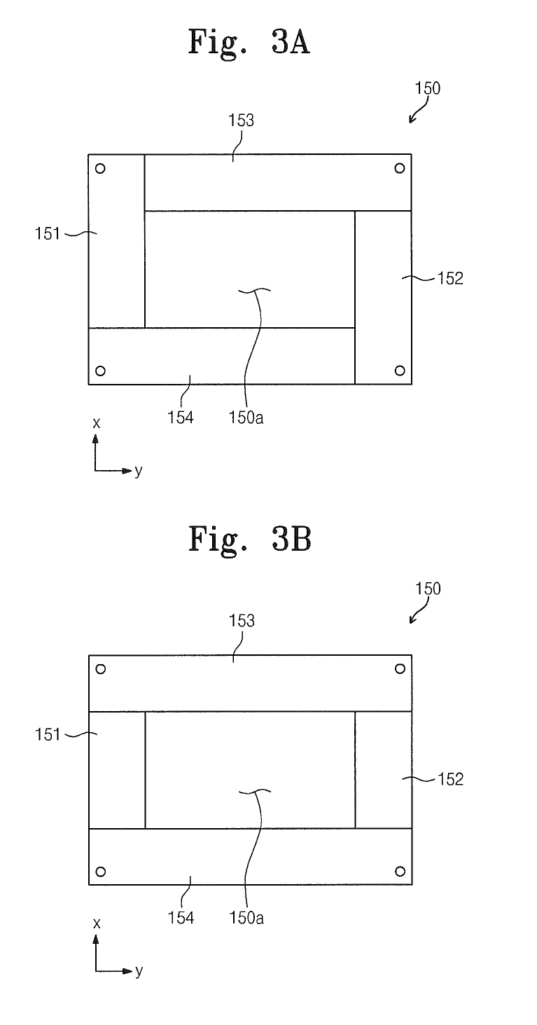

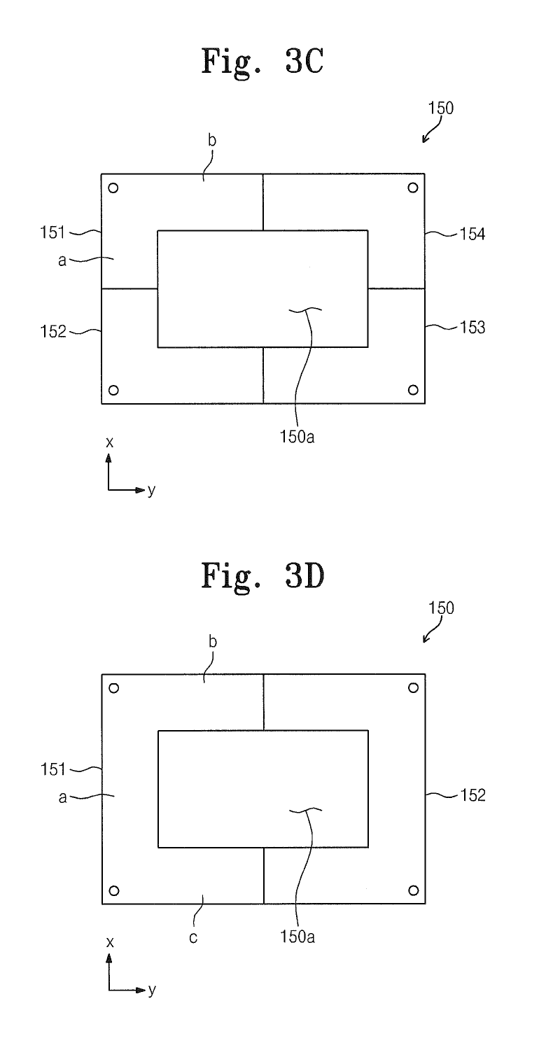

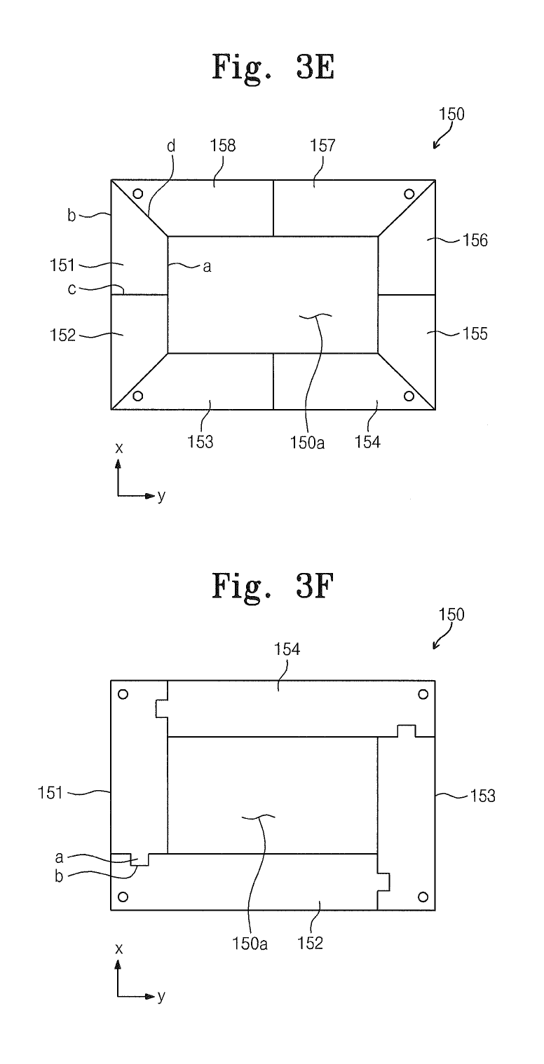

FIGS. 3A through 3F are plan views illustrating exemplary embodiments of insert members 150 according to the invention. In FIGS. 3A through 3F, stepped shapes of the insert members 150 are not illustrated for clarity in comparison of features of the insert member 150.

Referring to FIG. 3A, the insert member 150 includes four frames 151 to 154 (first to fourth frames). Each of the frames 151 to 154 has a rectangular parallelepiped shape. The first frame 151 is longitudinally parallel to the first direction X, and the second frame 152 is spaced apart from the first frame 151 and longitudinally parallel with the first frame 151. The third frame 153 is longitudinally parallel to the second direction Y, and the fourth frame 154 is spaced apart from the third frame 153 and parallel with the third frame 153. An end of the first frame 151 makes contact with a side of the fourth frame 154, and an end of the second frame 152 make contact with a side of the third frame 153. An end of the third frame 153 makes contact with a side of the first frame 151, and an end of the fourth frame 154 makes contact with a side of the second frame 152. The first and second frames 151 and 152 have the same length, and the third and fourth frames 153 and 154 have the same length. Since the third frame 153 is longer than the first frame 151, the insert member 150 has a rectangular rim shape which is longer in the second direction Y than in the first direction X. In a state where the first to fourth frames 151 to 154 are disposed as described above, the second opening 150a is formed by the sides of the first to fourth frames 151 and 154.

Referring to FIG. 3B, the insert member 150 is different from the insert member 150 shown in FIG. 3A in that first and second frames 151 and 152 are between third and fourth frames 153 and 154. First ends of the first and second frames 151 and 152 make contact with a side of the third frame 153, and second ends opposing the first ends of the first and second frames 151 and 152 make contact with a side of the fourth frame 154.

Referring to FIG. 3 C, first to fourth frames 151 to 154 have the same shape. Each of the first to fourth frames 151 to 154 includes a first region (a) and a second region (b). The first region (a) is parallel to the first direction X, and the second region (b) extends from an end of the first region (a) in a direction parallel to the second direction Y. The first to fourth frames 151 to 154 each including the first and second regions (a) and (b) is r-shaped (bracket shaped). The first to fourth frames 151 to 154 are sequentially arranged in a counterclockwise direction. An end of the first region (a) of the first frame 151 is in contact with an end of the first region (a) of the second frame 152, and an end of the second region (b) of the second frame 152 is in contact with an end of the second region (b) of the third frame 153. An end of the first region (a) of the third frame 153 is in contact with an end of the first region (a) of the fourth frame 154, and an end of the second region (b) of the fourth frame 154 is in contact with an end of the second region (b) of the first frame 151.

Referring to FIG. 3D, the insert member 150 includes two frames 151 and 152 (first and second frames). The first and second frames 151 and 152 have the same shape. Each of the first and second frames 151 and 152 include first to third regions (a), (b), and (c). The first region (a) is parallel to the first direction X, and the second region (b) extends from an end of the first region (a) in the second direction Y. The third region (c) extends from the opposing other end of the first region (a) in the second direction Y. The third region (c) faces the second region (b) and is parallel with the second region (b). The first and second frames 151 and 152 including the first to third regions (a), (b), and (c) has an approximately “C” shape. An end of the second region (b) of the first frame 151 is in contact with an end of the second region (b) of the second frame 152, and an end of the third region (c) of the first frame 151 is in contact with an end of the third region (c) of the second frame 152.

Referring to FIG. 3E, the insert member 150 includes eight frames 151 to 158. The frames 151 to 158 have the same shape, and when viewed from the topside, each of the frames 151 to 158 has four sides (a) to (d) (first to fourth sides). The first sides (a) form sides of the second opening 150a, and the second sides (b) are parallel with the first sides (a). The second sides (b) are longer than the first sides (a). The third sides (c) are perpendicular to the first sides (a) and are connected between ends of the first sides (a) and ends of the second sides (b). The fourth sides (d) are connected between the opposing other ends of the first sides (a) and the other ends of the second sides (b). The fourth sides (d) are sloped with respect to the third sides (c). Neighboring two of the third sides (c) of the frames 151 to 158 are in contact with each other, and neighboring two of the fourth sides (d) of the frames 151 to 158 are in contact with each other.

Referring to FIG. 3F, frames 151 to 154 include insertion protrusions (a) and insertion grooves (b), respectively. The insertion grooves (b) have a shape corresponding to the shape of the insertion protrusions (a). The insertion protrusions (a) are inserted in the insertion grooves (b) in a manner such that an insertion protrusion (a) is inserted in a neighboring insertion groove (b). Owing to the insertion protrusions (a) and the insertion grooves (b), the frames 151 to 154 can be firmly connected to each other.

As described above, if an insert member 150 includes a plurality of frames and the second opening 150a is defined by the assembled frames, inner surfaces of the insert member 150 defining the second opening 150a can be easily machined. If a one-piece insert member 150 is used, the second opening 150a may have to be formed directly in the insert member 150, and thus it may be difficult to machine inner surfaces of the insert member 150. Particularly, it may be more difficult to machine corners of the second opening 150a having a rectangular shape due to insufficient space. Thus, the surface roughness of inner sides of the insert member 150 may be increased, and thus the surface roughness of edges of a printed circuit film formed through a blanking process using the insert member 150 may be increased.

However, according to the invention, the second opening 150a is defined by inner edges of the detachable frames. Therefore, the frames can be easily machined after detaching the frames. In the case of the insert members 150 shown in FIGS. 3A, 3B, 3E, and 3F, since the second opening 150a is formed by inner edges of neighboring frames, machining of the corners of the second opening 150a can be easily carried out by machining the individual edges of the frames. In the case of the insert members 150 shown in FIG. 3C and 3D, since sides opposite to the first regions (a) can be opened, sufficient spaces can be ensured for machining the frames. Furthermore, according to the invention, the frames of the insert member 150 can be disassembled so as to further machine the inner edges of the frames which define the second opening 150a, such as by a wheel grinding process. For these reasons, inner sides of the frames which define the second opening 150a of the insert member 150 can be easily machined, and thus the surface roughness of the inner edges defining the second opening 150a can be reduced to decrease the surface roughness of edges of a printed circuit film formed through a blanking process using the insert member 150.

In a printed circuit film blanking process, the punch 250 is inserted in the second opening 150a of the insert member 150. At this time, the tolerance of gaps between the outer surfaces of the punch 250 and the inner surfaces of the second opening 150a may be maintained within a predetermined range so as to blank a printed circuit film having a low surface roughness. However, if the insert member 150 is one single unitary piece, it may be difficult to precisely machine the inner surfaces of the insert member 150, and thus the tolerance of the gaps between the outer surfaces of the punch 250 and the inner surfaces of the second opening 150a may not be maintained within a predetermined range. Therefore, machining errors may be increased, and manufacturing costs of the insert member 150 may be increased when the insert member 150 is one single unitary piece.

However, according to the invention, since the second opening 150a of the insert member 150 is defined by a plurality of frames, the size of the second opening 150a can be easily controlled. That is, the tolerance of the gaps between the inner surfaces of the second opening 150a and the outer surfaces of the punch 250 can be easily maintained within a predetermined range by machining the respective frames individually and/or separately and assembling the frames. Then, since machining errors may be reduced, the manufacturing costs of the insert member 150 may be reduced.

Referring again to FIGS. 1 and 2, the insert fixation part 160 is inserted in the insertion groove 116 to fix the insert member 150 to the first plate 110. The insert fixation part 160 includes a coupling part 161 and a fixation part 162. The coupling part 161 is coupled to a side of the insertion groove 116 of the first plate 110 by using a fastening member, such as bolts 164. The fixation part 162 is perpendicular to the coupling part 161 and extends from an upper end of the coupling part 161. The bottom side of an end 162a of the fixation part 162 is stepped like the stepped outer region 150b of the insert member 150. The end 162a of the fixation part 162 presses the outer region 150b of the insert member 150 in the third direction Z so that the insert member 150 can be fixed to the first plate 110. The first fixation part 162 includes an accommodation hole 166 open towards the insert member 150 and the guide bush 1402. The accommodation hole 166 extends from the end 162a of the fixation part 162 to a position close to the coupling part 161. The upper end of the guide bush 140 which is inserted in the bush hole 118 is placed at the accommodation hole 166. The fixation part 162 may be coupled to the first plate 110 by using a fastening member, such as bolts 165.

The punch unit 200 is above the die unit 100 and is vertically movable along the third direction Z. The punch unit 200 punches the base film M while it is supported on the die unit 100 to blank a printed circuit film. The punch unit 200 includes a second plate 210, lift bushes 220, packing parts 230, an auxiliary plate 240, the punch 250, the guide rods 260, and the fixation pins 270.

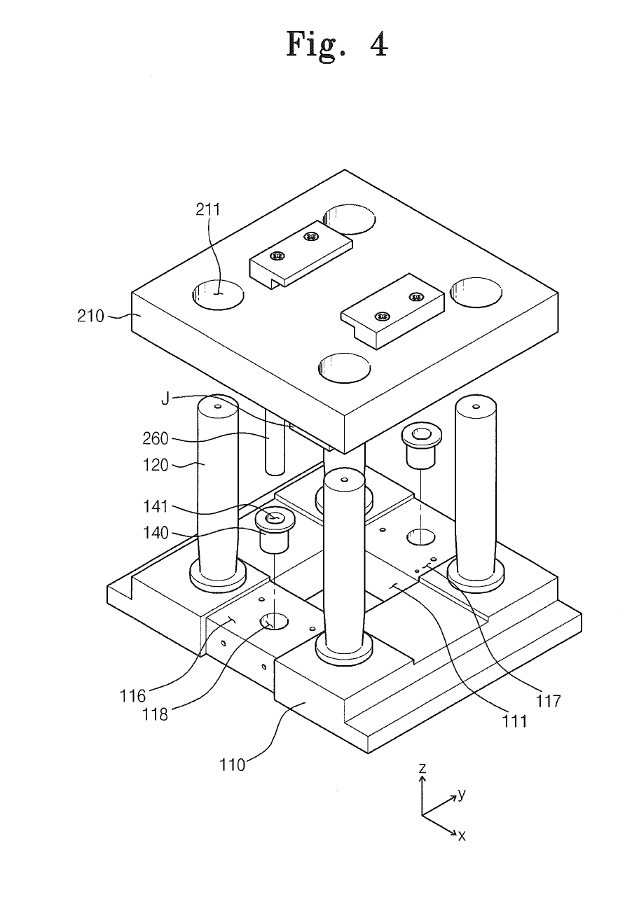

The second plate 210 has a shape corresponding to the shape of the first plate 110 and is above the first plate 110. The second plate 210 includes insertion holes 211 (refer to FIG. 4) which extend completely through a thickness of the second plate 210. The insertion holes 211 are penetration holes which extend from the top surface to the bottom surface of the second plate 210. In the embodiment, four insertion holes 211 are in the second plate 210 and are spaced apart from each other. Coupling structures 218 are on the top surface of the second plate 210. The coupling structures 218 are connected to a punch unit lift (not shown). The punch unit 200 may be vertically moved by operating the punch unit lift.

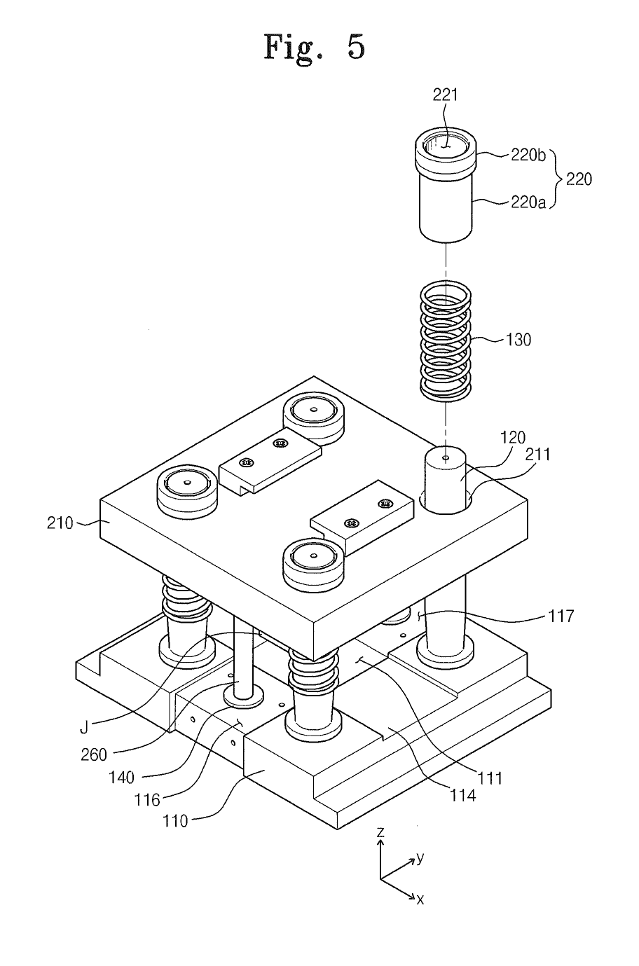

The lift bushes 220 are inserted in the insertion holes 211, respectively. The lift bushes 220 include lift holes 221 (refer to FIG. 5) in the lift bushes 220, respectively. The lift holes 221 are penetration holes which extend from the top surfaces to the bottom surfaces of the lift bushes 220. The lift holes 221 in the lift bushes 220 have a radius corresponding to the radius of the outer surface of the lift rods 120. The lift rods 120 are inserted in the lift holes 221, and when the punch unit 200 is vertically moved, the lift bushes 220 are moved along the lift rods 120.

Each of the lift bushes 220 includes an insertion part 220a and a stopper part 220b. The size of the outer surface of the insertion part 220a corresponds to the size of the inner surface of the insertion hole 211. The insertion part 220a is inserted between the inner surface of the insertion hole 211 and the outer surface of the lift rod 120. The stopper part 220b is connected to the upper end of the insertion part 220a, and the radius of the outer surface of the stopper part 220b is greater than the radius of the outer surface of the insertion part 220a. Owing to the stopper part 220b of the lift bush 220, the lift bush 220 is not completely inserted in the insertion hole 211.

The packing parts 230 are fixed to the upper ends of the lift rods 120. The packing parts 230 has a radius greater than the radius of the lift holes 221 of the lift bushes 220 to prevent the lift bushes 220 from being detached from the lift rods 120. The packing parts 230 may be coupled to the upper ends of the lift rods 120 by using fastening members such as bolts 231.

The auxiliary plate 240 is at a bottom surface of the second plate 210 and is fixed to the bottom side of the second plate 210. The auxiliary plate 240 supports the punch 250, the guide rods 260, and the fixation pins 270.

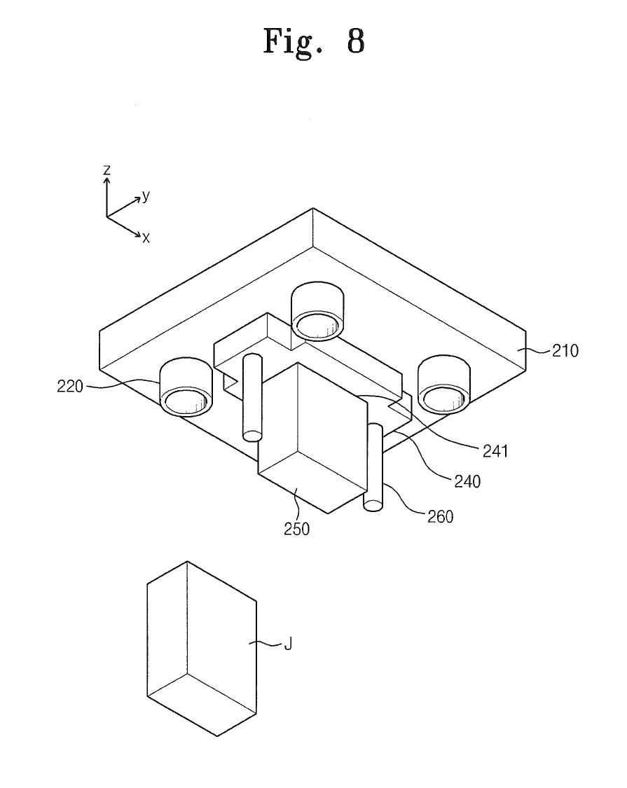

The punch 250 is at the bottom side of the second plate 210. The upper end of the punch 250 is inserted in an accommodation hole 241 (refer to FIG. 8) in the auxiliary plate 240. The punch 250 has a rectangular parallelepiped block shape. The bottom side of the punch 250 corresponds to or is smaller than the second opening 150a of the insert member 150. When the punch unit 200 is moved down, the punch 250 punches the base film M which is placed on the insert member 150 and is placed in the second opening 150a of the insert member 150 to blank a printed circuit film.

The fixation pins 270 are close to the punch 250 and parallel to the third direction Z. The number of the fixation pins 270 is four. When the punch 250 punches the base film M, distal ends of the fixation pins 270 are inserted sequentially into fixation holes M1 of the base film M and the pin holes 158 of the insert member 150. That is, when the punch 250 punches the base film M, the fixation pins 270 reduce or effectively prevent deviation of the base film M from a blanking position. Elastic members 275 are provided on the upper ends of the fixation pins 270. When the fixation pins 270 are inserted in fixation holes M1 of the base film M and the pin holes 158 of the insert member 150 as the punch unit 200 is moved down, the elastic members 275 are compressed, and when the punch unit 200 is moved upward, the elastic members 275 are decompressed. Owing to the elastic members 275, the fixation pins 270 can be returned to their original positions after a blanking action.

The guide rods 260 are at the bottom side of the auxiliary plate 240 and have a rod shape. The guide rods 260 are parallel to the third direction Z, and the upper ends of the guide rods 260 are fixed to the bottom side of the auxiliary plate 240. The distal lower ends of the guide rods 260 are inserted in the guide holes 141 of the guide bush 140. As the punch unit 200 is vertically moved, the guide rods 260 are moved in the guide holes 141. Owing to the guide rods 260, the position of the punch unit 200 can be fixed relative to the first plate 110 in the first and second directions X and Y, and thus the punch 250 can precisely punch the base film M.

An exemplary embodiment of a method of blanking a printed circuit film using the printed circuit film blanking apparatus 10 will now be explained.

The printed circuit film blanking method includes a position setting operation, an assembling operation, and a blanking operation. In the position setting operation, the die unit 100 and the punch unit 200 are placed in blanking positions where a printed circuit film can be blanked using the punch 250. In the assembling operation, the insert member 150 is placed on the die unit 100, and the punch 250 is placed on the punch unit 200. In the blanking operation, the punch 250 punches the base film M which is placed on the insert member 150 to blank a printed circuit film. Hereinafter, each operation will be described in detail.

FIGS. 4 and 5 are views for explaining an exemplary embodiment of the position setting operation according to the invention.

Referring to FIGS. 4 and 5, the second plate 210 is placed so that the lift rods 120 are inserted in the insertion holes 211, and the elastic members 130 are inserted in the insertion holes 211. The elastic members 130 are around the lift rods 120 so that the elastic members 130 surround the lift rods 120. The positions of the first plate 110 and the second plate 210 are adjusted relative to each other. The guide rods 260 are inserted in the guide holes 141 of the guide bushes 140, and in a state where a jig (J) is placed at a blanking position, the lift bushes 220 are coupled to the lift rods 120 so that the lift rods 120 can be inserted in the lift holes 221 of the lift bushes 220.

Next, the insertion parts 220a of the lift bushes 220 are placed between the inner surfaces of the insertion holes 211 in the second plate 210 and the outer surfaces of the lift rods 120 to fix the position of the second plate 210 relative to the first plate 110. The blanking position is a position where the punch 250 can precisely punch the base film M. In this position setting operation, the jig J is placed at a position where the punch 250 to be placed, and then the jig J is replaced with the punch 250 in the next assembling operation. That is, after the relative positions of the first plate 110 and the second plate 210 are fixed, the insert member 150 and the punch 250 are placed in the next assembling operation.

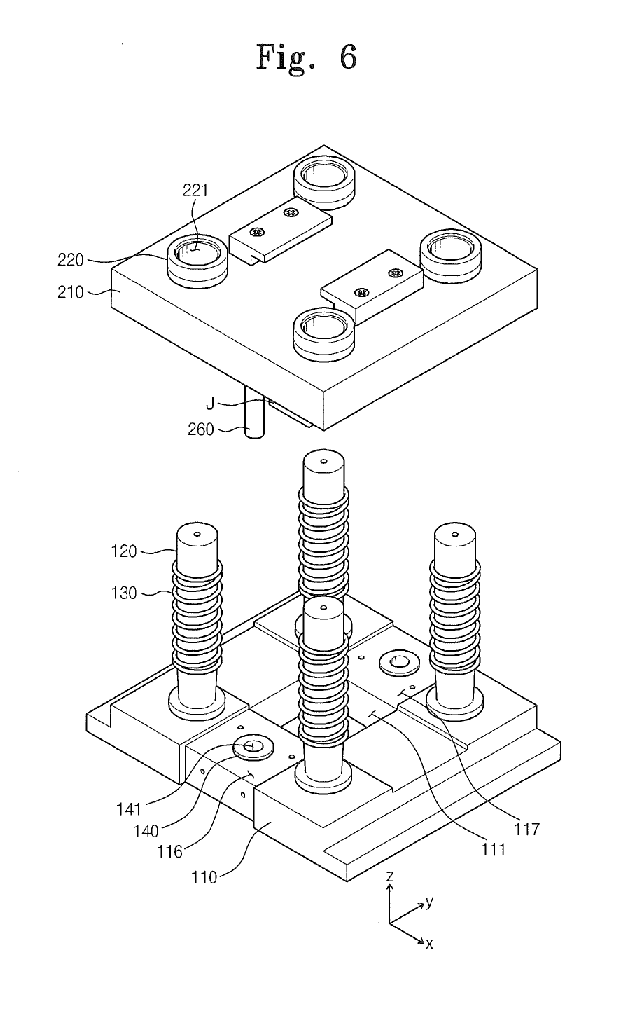

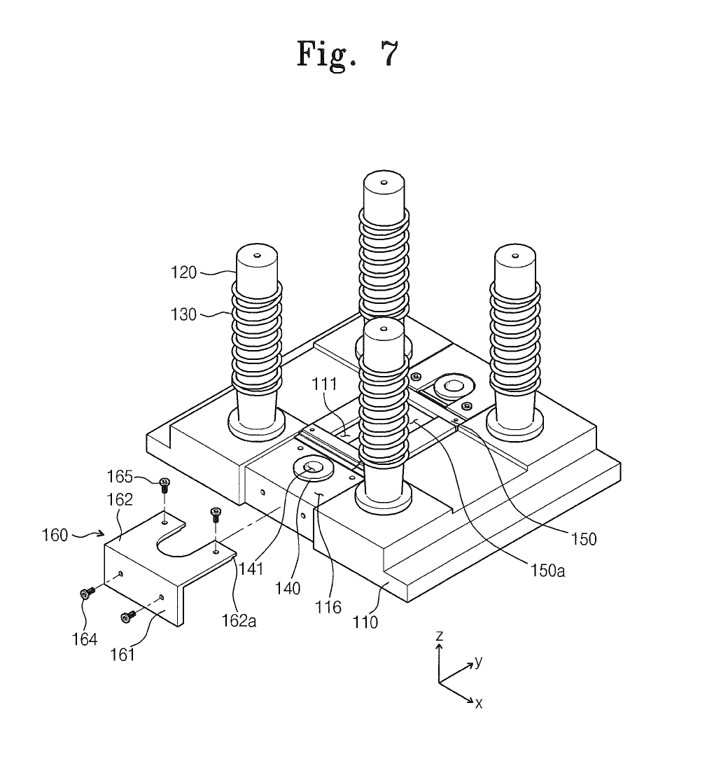

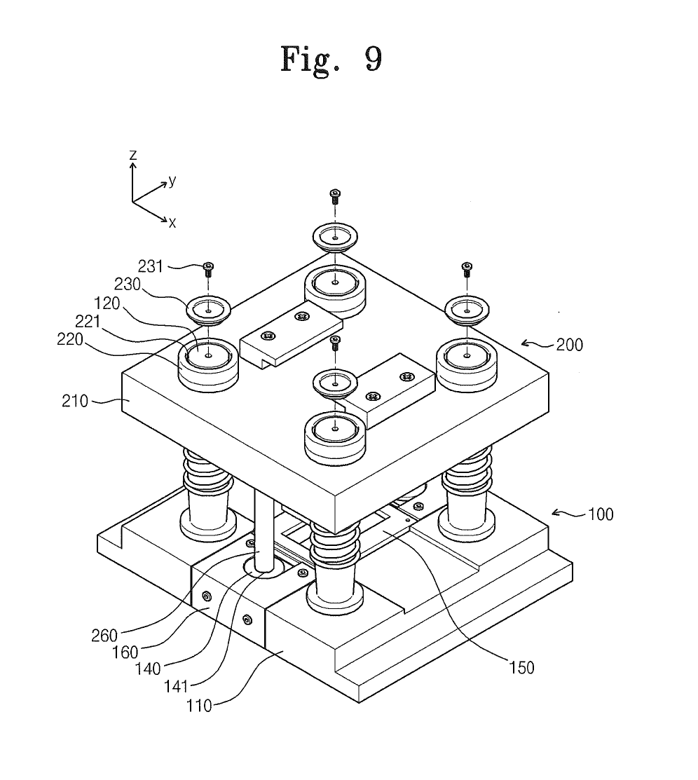

FIGS. 6 through 9 are views for explaining an exemplary embodiment of the assembling operation according to the invention.

Referring to FIGS. 6 through 9, the second plate 210 is moved upward to separate the lift rods 120 from the lift holes 221 of the lift bushes 220. Next, the insert member 150 is placed on the top surface of the first plate 110 in a manner such that both ends of the insert member 150 are placed on the bottom surfaces of the insertion grooves 116 and 117 of the first plate 110. Then, the second opening 150a of the insert member 150 is placed at the upper side of the first opening 111 of the first plate 110. Next, the insert fixation parts 160 are placed in the insertion grooves 116 and 117 and are coupled to the first plate 110 using the bolts 164 and 165. The bottom sides of the ends 162a of the insert fixation parts 160 are engaged with the outer regions 150b of the insert member 150 and push the outer regions 150b downwardly. Thus, the insert member 150 is fixed to the top surface of the first plate 110.

The jig J placed on the auxiliary plate 240 in the position setting operation is replaced with the punch 250. In detail, the jig J is detached from the accommodation hole 241 of the auxiliary plate 240, and the punch 250 is inserted in the accommodation hole 241. In the illustrated embodiment, the jig J has the same shape as the shape of the punch 250. In detail, the jig J has a rectangular parallelepiped block shape, and the bottom side of the jig J has a shape in dimensions substantially equal to or smaller than the second opening 150a of the insert member 150.

After the insert member 150 and the punch 250 are assembled, the second plate 210 is moved downward so that the lift rods 120 can be inserted in the lift holes 221 of the lift bushes 220, and the guide rods 260 can be inserted in the guide holes 141 of the guide bushes 140. Since the relative positions of the first plate 110 and the second plate 210 are set to blanking positions in the position setting operation of FIGS. 4 and 5, the die unit 100 and the punch unit 200 can be placed in the blanking positions only by inserting the lift rods 120 in the lift holes 221. After the lift rods 120 are inserted in the lift holes 221, the packing parts 230 are coupled to the upper ends of the lift rods 120 using bolts 231. The packing parts 230 reduce or effectively prevent deviation of the lift rods 120 from the lift holes 221.

Then, the blanking operation is performed using the printed circuit film blanking apparatus 10 assembled as described above.

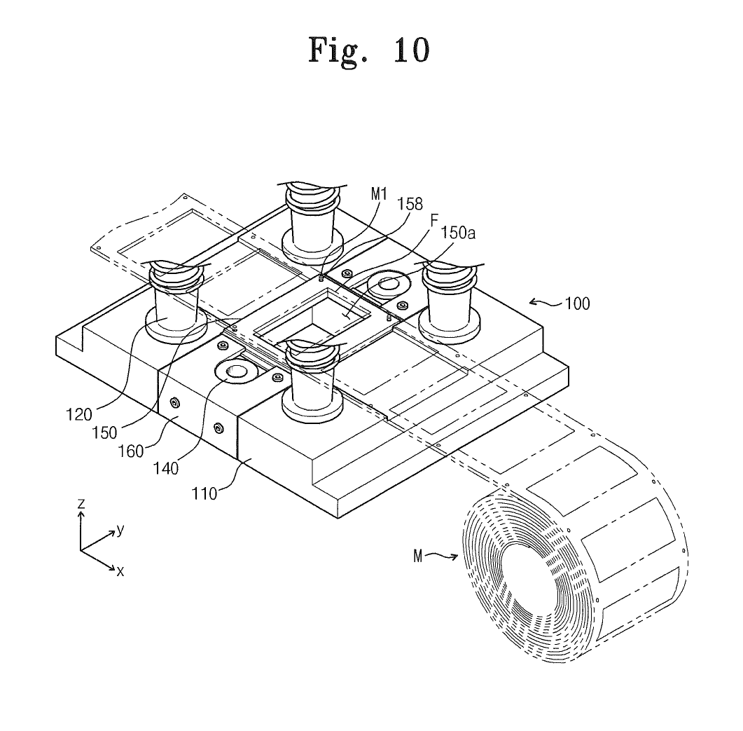

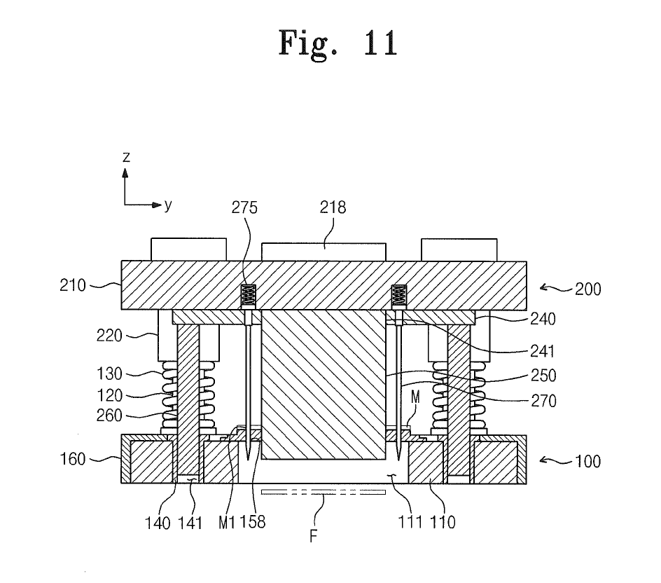

FIG. 10 is a perspective view illustrating an exemplary embodiment of a portion of the base film M supported on the die unit 100 according to the invention; and FIG. 11 a cross-sectional view for explaining an exemplary embodiment of the blanking operation for blanking a printed circuit film using the punch unit 200 according to the invention.

Referring to FIGS. 10 and 11, the base film M is provided in the form of a roll. The base film M is fed to the die unit 100 while being unrolled. A plurality of printed circuit films F are arranged on the base film M at predetermined intervals in the length direction of the base film M. Electrical interconnections are formed in the printed circuit films F. Insulation films which cover the interconnections and insulate the interconnections are formed. The printed circuit films F may be blanked in proper size. Then, integrated circuit chips may be placed on the printed circuit films F, and the printed circuit films F may be used in display devices.

Fixation holes M1 are formed in the base film M at positions close to the printed circuit films F, but not in the printed circuit films F. In the illustrated embodiment, four fixation holes M1 are formed around one printed circuit film F at positions close to the corners of the printed circuit film F. The base film M is placed on the insert member 150 in a manner such that a printed circuit film F is placed at the upper side of the second opening 150a of the insert member 150, and the fixation holes M1 are aligned with the pin holes 158 of the insert member 150.

After the base film M is placed on the insert member 150, the punch unit 200 is moved downward. Then, as the second plate 210 is moved downward, the lift bushes 220 are moved down along the lift rods 120, and thus the elastic members 130 are compressed. The guide rods 260 are moved downward along the guide holes 141 of the guide bushes 140. The distal ends of the fixation pins 270 are sequentially inserted into the fixation holes M1 and the pin holes 158 to fix the base film M to the insert member 150. The elastic members 275 on the upper ends of the fixation pins 270 are compressed. The punch 250 punches the base film M placed on the insert member 150 and is inserted in the second opening 150a so that the printed circuit film F can be blanked. The blanked printed circuit film F moves down through the first opening 111 of the first plate 110. After the printed circuit film F is blanked, the punch unit 200 is moved upward to its original position by the resilience of the elastic members 130. The base film M is fed so that the next printed circuit films F of the base film M are sequentially placed on the insert member 150, such that the blanking operation is performed.

As described above, in the position setting operation of the printed circuit film blanking method of the invention, the relative positions of the die unit 100 and the punch unit 200 are fixed to the blanking positions by using the jig J having the same shape as the punch 250. Thereafter, the jig J is replaced with the punch 250 in the assembling operation for using the punch 250 in the blanking operation. Therefore, the punch 250 can be precisely inserted in the second opening 150a of the insert member 150 in the blanking operation.

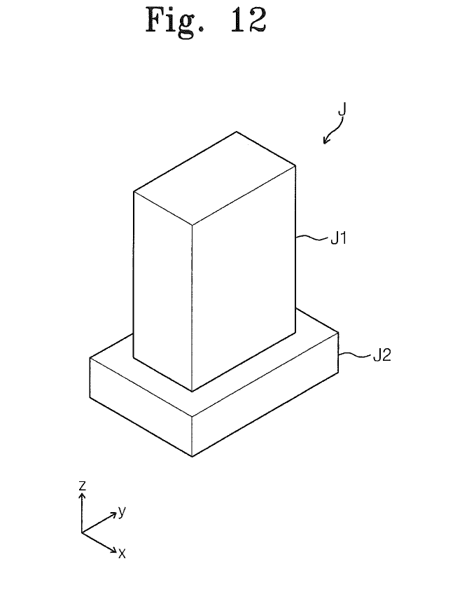

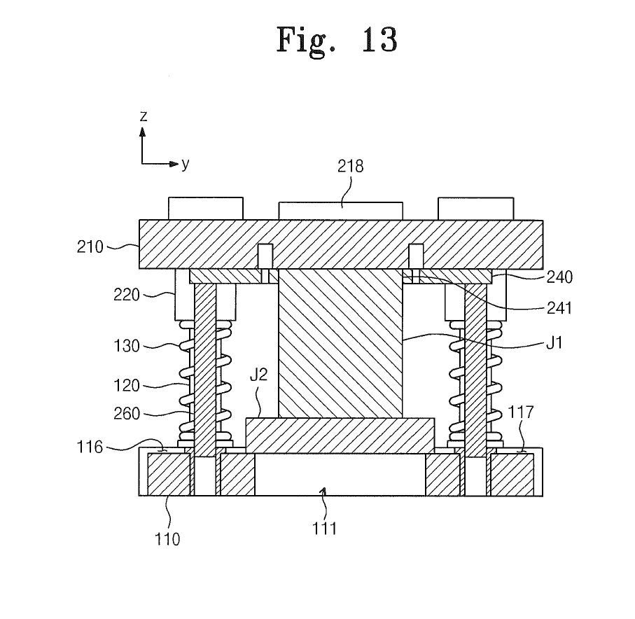

FIG. 12 is a perspective view illustrating another exemplary embodiment of a jig J according to the invention, and FIG. 13 is a cross-sectional view for explaining an exemplary embodiment of a position setting operation using the jig J of FIG. 12 according to the invention.

Referring to FIGS. 12 and 13, the jig J includes an upper body J1 and a lower body J2. The upper body J1 has a rectangular parallelepiped block shape, and the topside of the upper body J1 is inserted in the accommodation hole 241 of the auxiliary plate 240. The lower body J2 is under the upper body J1 and is connected to the lower end of the upper body J1. The bottom side of the lower body J2 is bigger than the second opening 150a of the insert member 150. In an embodiment, the size of the lower body J2 corresponds to the size of the insert member 150. The upper body J1 may correspond to the size of the punch 250.

In a position setting operation, both of opposing ends of the lower body J2 are placed on the bottom sides of the insertion grooves 116 and 117 of the first plate 110, respectively. In this state, the lift bushes 220 are around the lift rods 120 to fix the relative positions of the die unit 100 and the punch unit 200 to blanking positions. Since the area of the bottom side of the lower body J2 corresponds to the area of the insert member 150, the insert member 150 can be placed on a position where the lower body J2 was placed. Thus, when the punch 250 replaces the jig J in an assembling operation, the punch 250 can be exactly positioned so that the punch 250 can be inserted in the second opening 150a of the insert member 150. That is, the relative positions of the punch 250 and the second opening 150a can be easily set to blanking positions.

The above-disclosed subject matter is to be considered illustrative and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

According to the invention, the inner surface of the insert member which defines the opening of the insert member can be more precisely grinded, and thus printed circuit films having low surface roughness at their edges can be produced by blanking.

According to the invention, the inner surface defining the opening of the insert member can be easily grinded, and thus manufacturing cost of the insert member necessary for grinding the opening can be reduced.

According to the invention, a tolerance of a gap between the opening of the insert member and the punch can be easily controlled by adjusting the size of the opening of the insert member, and thus printed circuit films having low surface roughness at their edges can be produced by blanking.

The invention has been illustratively explained. Although exemplary embodiments of the invention have been described, the invention may be embodied in different combinations thereof, forms, and environments. That is, various changes in forms and details may be made within the scope of the invention by those of ordinary skill in the art. While the invention has been explained with reference to exemplary embodiments, various changes in forms and details may be made therein according to application fields and purposes. The exemplary embodiments should be considered in descriptive sense only and not for purposes of limitation. Thus, it should be construed that the appended claims include other embodiments.

What is claimed is:

1. An apparatus for blanking a printed circuit film from a base film including a plurality of printed circuit films, the apparatus comprising:
a die unit which supports the base film; and
a vertically movable punch unit which is above the die unit and comprises a punch which punches the base film while the base film is on the die unit, such that the printed circuit film is blanked from the base film,
wherein the die unit comprises:
a plate; and
an insert member which is on a top surface of the plate and supports a region of the base film which is punched, the insert member comprising:
an opening which receives the punch, and
a plurality of assembled, detachable frames, wherein the opening of the insert member is defined by the assembled frames.

2. The apparatus of claim 1, wherein the insert member has a tetragonal rim shape.

3. The apparatus of claim 2, wherein the insert member comprises four frames each having a rectangular parallelepiped shape.

4. The apparatus of claim 3, wherein
an end of one of the frames contacts a side of an adjacent frame.

5. The apparatus of claim 3, wherein one side of the opening is defined by one side of one of the frames.

6. The apparatus of claim 3, wherein the frames comprise:
a first frame;
a second frame which is spaced apart from the first frame and parallel with the first fame;
a third frame perpendicular to the first frame, the third frame comprising a first end which contacts a side of the first frame and a second end which opposes the first end and contacts a side of the second frame; and
a fourth frame which is spaced apart from the third frame and parallel with the third frame, the fourth frame comprising a first end which contacts the side of the first frame and a second end which opposes the first end and contacts the side of the second frame.

7. The apparatus of claim 2, wherein the insert member comprises two frames having the same shape,
wherein each of the frames comprises:
a first region;
a second region which extends from a first end of the first region, in a direction perpendicular to the first region; and
a third region which extends from a second end of the first region which opposes the first end, in a direction perpendicular to the first region, the third region facing the second region.

8. The apparatus of claim 2, wherein the insert member comprises four frames having the same shape and size,
wherein each of the frames comprises:
a first region; and
a second region which extends from one end of the first region, in a direction perpendicular to the first region.

9. The apparatus of claim 2, wherein the insert member comprises eight frames having the same shape,
wherein each of the eight frames comprises:
a first side;
a second side parallel with the first side and longer than the first side;
a third side perpendicular to the first side, wherein the third side connects a first end of the first side and a first end of the second side; and
a fourth side which connects a second end opposing the first end of the first side and a second end opposing the first end of the second side.

10. The apparatus of claim 2, wherein each of the frames comprises:
an insertion protrusion; and
an insertion groove having a shape which corresponds to the insertion protrusion, and receives the insertion protrusion of an adjacent frame.

11. The apparatus of claim 2,
wherein a portion of the frames includes a first stepped portion at an outer region of the frame, such that a top surface of the outer region of the frame is lower than a top surface of an inner region of the frame adjacent to the opening,
wherein the die unit further comprises an insert fixation part which is coupled to the plate, an end of the insert fixation part including a second stepped portion in a shape which corresponds to the outer region of the frame, and
wherein a bottom surface of the second stepped portion of the insert fixation part contacts the top surface of the outer region of the frame.

12. An insert member for a printed circuit film blanking apparatus in which a portion of a base film including a plurality of printed circuit films is supported on the insert member and is punched by a punch to blank a printed circuit film, the insert member comprising;
detachable frames assembled in a tetragonal rim shape; and
an opening which receives the punch and is defined by inner edges of the detachable frames.

13. The insert member of claim 12, wherein the insert member comprises four frames each having a rectangular parallelepiped shape.

14. The insert member of claim 12, wherein the insert member comprises two frames having the same “C”-shape.

15. The insert member of claim 12, wherein the insert member comprises four frames having the same [symbol] -shape (bracket shape).

16. A method of blanking a printed circuit film, the method comprising:
providing an insert member comprising an opening;
placing a portion of a base film comprising a plurality of printed circuit films on a top surface of the insert member; and
blanking the printed circuit film by lowering a punch from an upper side of the insert member into the opening of the insert member,
wherein the insert member further comprises a plurality of detachable frames which are assembled and define the opening.

17. The method of claim 16, wherein prior to the providing the insert member, the method further comprises performing a position setting operation to fix positions of a first plate which receives the insert member and a second plate on which the punch is disposed to blanking positions, so as to blank the printed circuit film using the punch,
wherein the position setting operation is performed in a state where the punch is detached and a jig is attached to a position from which the punch is detached.

18. The method of claim 17, wherein the jig has the same shape as the punch.

19. The method of claim 17, wherein a bottom surface of the jig is wider than the opening of the insert member.

20. The method of claim 17, wherein the providing the insert member comprises:
detaching the jig from the position and attaching the punch to the position; and
placing the first plate and the second plate at the blanking positions.
